(19) United States
(12) Patent Application Publication
(10) Pub. No.: US 2010/0201290 A1
(43) Pub. Date: Aug. 12, 2010

(54) PIEZOELECTRIC ACTUATOR FAULT RECOVERY SYSTEM AND METHOD

(76) Inventors: Richard Becker, Camarillo, CA (US); Michael C. Cheiky, Thousand Oaks, CA (US)

Correspondence Address: SHEPPARD, MULLIN, RICHTER & HAMPTON LLP, 12275 EL CAMINO REAL, SUITE 200, SAN DIEGO, CA, 92130, US

(21) Appl. No.: 12/652,681

(22) Filed: Jan. 5, 2010

Related U.S. Application Data
(60) Provisional application No. 61/144,265, filed on Jan. 13, 2009.

(51) Int. Cl. H01L 41/09

(52) U.S. Cl. 318/116

(57) ABSTRACT

The present invention provides a system and method of piezoelectric fault recovery comprising: monitoring a set of operational piezoelectric elements of a piezoelectric actuator, detecting a failure of an element of the set, removing the failed element from the set, and rerouting the drive signal sent to the element according to a predetermined behavior preference.

### CROSS-REFERENCE TO RELATED APPLICATIONS

This application claims priority from U.S. Provisional Patent Application Ser. Nos. 61/144,265, filed Jan. 13, 2009, which is hereby incorporated herein by reference in its entirety.

### TECHNICAL FIELD

The present invention relates to piezoelectric devices, and more particularly, some embodiments relate to fault control systems in piezoelectric actuators.

### DESCRIPTION OF THE RELATED ART

Piezoelectric actuators utilize the converse piezoelectric effect to create a mechanical displacement in response to an applied voltage. Such actuators may be used in applications such as machine tools, disk drives, military applications, ink delivery systems for printers, medical devices, precision manufacturing, fuel injection, or any application which requires high precision or high speed fluid delivery.

In most actuators, a single piezoelectric element is used to mechanically actuate the device. Systems requiring a higher degree of precision and predictability may utilize an actuator with multiple piezoelectric elements. In such systems, each individual piezoelectric element may be independently driven. However, when an element of such a piezoelectric actuator fails, the element will behave like a short circuit, and often damage or disable the entire actuator.

### BRIEF SUMMARY OF EMBODIMENTS OF THE INVENTION

According to various embodiments of the invention, a system and method of multi-element piezoelectric actuator fault recovery is presented. A plurality of piezoelectric elements of a piezoelectric actuator and their corresponding driving signals are monitored. If an element fails, it is removed from the list of elements and the driving signals are rerouted so that the driving signal with the least impact on actuator performance is removed.

According to an embodiment of the invention, a method of piezoelectric fault recovery comprises: monitoring a set of operational piezoelectric elements of a piezoelectric actuator; detecting a failure of an element of the set; and removing the failed element from the set.

According to a further embodiment of the invention, the step of removing further comprises disabling the actuator if less than a predeteimined number of elements remain in the set of monitored elements.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

### BRIEF DESCRIPTION OF THE DRAWINGS

The present invention, in accordance with one or more various embodiments, is described in detail with reference to the following figures. The drawings are provided for purposes of illustration only and merely depict typical or example embodiments of the invention. These drawings are provided to facilitate the reader's understanding of the invention and shall not be considered limiting of the breadth, scope, or applicability of the invention. It should be noted that for clarity and ease of illustration these drawings are not necessarily made to scale.

Some of the figures included herein illustrate various embodiments of the invention from different viewing angles. Although the accompanying descriptive text may refer to such views as “top,” “bottom” or “side” views, such references are merely descriptive and do not imply or require that the invention be implemented or used in a particular spatial orientation unless explicitly stated otherwise.

FIG. 1 depicts a fault recovery system according to an embodiment of the invention.

FIG. 2 is a flowchart illustrating an example method of fault control as practiced by an embodiment of the invention.

FIG. 3 is a flowchart illustrating a particular embodiment of a three-element piezoelectric actuator fault recovery system and method.

FIG. 4 is a flowchart illustrating the first piezoelectric element recovery subroutine of a particular embodiment of a three-element piezoelectric actuator fault recovery system and method.

FIG. 5 is a flowchart illustrating the second piezoelectric element recovery subroutine of a particular embodiment of a three-element piezoelectric actuator fault recovery system and method.

FIG. 6 is a flow chart illustrating the third piezoelectric element recovery subroutine of a particular embodiment of a three-element piezoelectric actuator fault recovery system and method.

FIG. 7 illustrates an exemplary computing module, which may be used to implement various components in particular embodiments of the invention.

The figures are not intended to be exhaustive or to limit the invention to the precise form disclosed. It should be understood that the invention can be practiced with modification and alteration, and that the invention be limited only by the claims and the equivalents thereof.

### DETAILED DESCRIPTION OF THE EMBODIMENTS OF THE INVENTION

Before describing the invention in detail, it is useful to describe an example environment with which the invention can be implemented. One such example is that of a driver for a multi-element piezoelectric actuator used in a fuel injector.

A more particular example is that of a fuel injector for dispensing fuel into a combustion chamber of an internal combustion engine, wherein injector pressure and temperature is high enough that the fuel charge operates as a super-critical fluid. An example of this type of fuel injector is disclosed in U.S. Pat. No. 7,444,230, herein incorporated by reference in its entirety.

Another such environment is a piezoelectric actuator driver of the type described in U.S. patent application Ser. No. 12/686,247, U.S. patent application Ser. No. 12/652,679, or U.S. patent application Ser. No. 12/686,298, each of which is herein incorporated by reference in its entirety. Another environment is system for defining a piezoelectric actuator waveform of the type described in U.S. Provisional patent application Ser. No. 12/652,674, which is hereby incorporated by reference in its entirety.

Another example is a piezoelectrically actuated fuel injector, for example, of the type disclosed in U.S. Provisional Patent Application No. 61/081,326, having a piezo actuated injector pin having a heated portion and a catalytic portion; and a temperature compensating unit; wherein fuel is dispensed into a combustion chamber of an internal combustion engine.

From time-to-time, the present invention is described herein in terms of these example environments. Description in terms of these environments is provided to allow the various features and embodiments of the invention to be portrayed in the context of an exemplary application. After reading this description, it will become apparent to one of ordinary skill in the art how the invention can be implemented in different and alternative environments.

Unless defined otherwise, all technical and scientific teens used herein have the same meaning as is commonly understood by one of ordinary skill in the art to which this invention belongs. All patents, applications, published applications and other publications referred to herein are incorporated by reference in their entirety. If a definition set forth in this section is contrary to or otherwise inconsistent with a definition set forth in applications, published applications and other publications that are herein incorporated by reference, the definition set forth in this section prevails over the definition that is incorporated herein by reference.

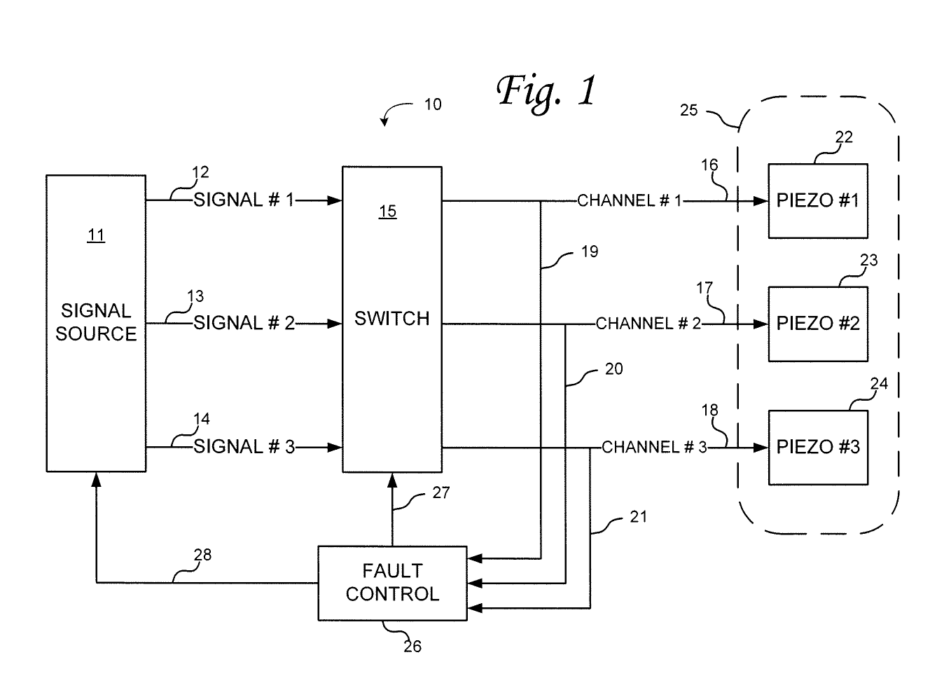

FIG. 1 depicts a fault recovery system according to an embodiment of the invention. A switch is controlled by a fault control module and is configured to transmit a plurality of signals provided by a signal source to piezoelectric elements of a multi-element piezoelectric actuator. Signal source 11 provides a plurality of signals (signals 12, 13, and 14 in the illustrated embodiment) configured to drive piezoelectric elements 22, 23, and 24 of a piezoelectric actuator 25. Signal source 11 may comprise any piezoelectric driving circuit, such as a piezoelectric driver of the type described in co-pending U.S. patent application Ser. No. 12/686,247, the contents of which are hereby incorporated by reference in its entirety. In other embodiments, signal source 11 could comprise a wavefoiin generator circuit or a plurality of wavefoiin generators that provide a plurality of piezoelectric driving signals.

Switch 15 is configured to receive the plurality of signals 12, 13, and 14, and to transmit those signals along channels 16, 17, and 18. Switch 15 may comprise, for example, an analog switch or analog switch matrix, or a relay or plurality of relays. Switch 15 is further configured to allow the fault control module 26 to control which signal is sent along which channel and to switch any signal off. For example, in a default state, switch 15 may be configured to transmit signal #1 12 along channel #1 16, signal #2 13 along channel #2 17, and signal #3 14 along channel #3 18. If, for example, piezoelectric element #1 22 were to meet a fault condition, switch 15 may be configured to reroute signal #1 to channel #2 and to switch signal #2 off at the instruction of the fault control module.

Fault control module 26 is configured to monitor the plurality of piezoelectric elements 22, 23, and 24 and control the signal routing in case of a fault. Fault control module 26 may monitor the piezoelectric elements using lines 19, 20, and 21. The monitoring may comprise any inspection that may indicate a failure or impending failure of a piezoelectric element. For example, fault control module 26 may determine that a fault has occurred if the voltage across a piezoelectric element drops below a certain predetermined threshold voltage. The predetermined threshold voltage may vary depending on the application of the embodiment. For example, in a multi-element piezoelectric actuator using lead zirconate titanate to actuate a fuel injector, the predetermined threshold voltage may be approximately 130 volts. In this case, fault control module 26 may be configured to reroute the signal previously sent to the failed piezoelectric element or to turn that signal off using switch 15. In further embodiments, fault control module 26 may be configured to send an error message or code to the device or environment employing the piezoelectric actuator. For example, in an embodiment used in a piezoelectric actuated fuel injector, the fault control module 26 may be configured to provide an error code to the vehicle's electronic control unit.

In further embodiments, fault control module 26 may be coupled to signal source 11, and may be configured to control or modify the signals provided by signal source 11 in the case of a fault. For example, if it detects a fault event, fault control module 26 may instruct the signal source 11 to cease sending the signal that was previously being sent to the failed piezoelectric element. In embodiments employing a piezoelectric driver of the type disclosed in copending U.S. patent application Ser. No. 12/686,247, fault control module 26 may be configured to cause signal source 11 to provide new signals to the remaining functional piezoelectric elements. For example, signal source 11 may have a predetermined plurality of preprogrammed contingency signals that allow the piezoelectric actuator 25 to continue operation until it can be repaired.

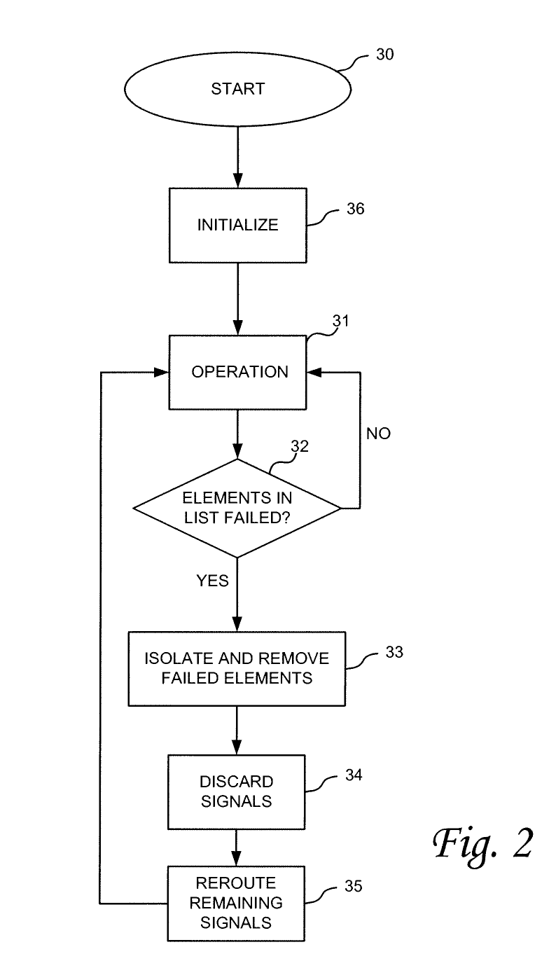

FIG. 2 is a flowchart illustrating an example method of fault control as practiced by an embodiment of the invention. At start 30, the system is an initial configuration 36. At initial configuration 36: (a) all of the piezoelectric elements are at the proper operating voltage; (b) a list of monitored piezoelectric elements is populated with each of the piezoelectric elements in a piezoelectric actuator; and (c) each of the driving signals is routed to an element in the list. The proper operating will depend on the application of the embodiment. For example, in a multi-element piezoelectric actuator using lead zirconate titanate to actuate a fuel injector, the proper operating voltage may be between 150 V to 160 V. During operation 31, the actuator is operated by transmitting the routed driving signals to their corresponding monitored piezoelectric elements. At inspection step 32, each element in the list of monitored elements is inspected to determine if the element is still operational. In a particular embodiment, each monitored element is inspected to determine if the voltage across the element while the actuator is inactive is below a predetermined threshold voltage. If the voltage across the element is below the threshold, the element is considered shorted. If no elements in the monitored list have failed, then no change occurs and operation step 31 is performed again. If any elements are determined to have failed, then at step 33 the failed elements are isolated and removed from the list of monitored elements. At step 34, one driving signal is discarded for each failed element according to which signals can be omitted while maintaining the least deviation from desired actuator operation. For example, in a four-element actuator where one element has failed, the driving signal which results in the least deviation from linear displacement according to time could be discarded. As another example, in a three-element actuator used to actuate a driveshaft of a fuel injector, the driving signal which corresponds to the fuel injector's highest power setting could be discarded to allow the injector to continue operation at a lower power setting. At step 35, the remaining driving signals are rerouted to the remaining elements of the monitored list of piezoelectric elements. The system then continues normal operation 31; however, the list of monitored elements and routed signals has now been decreased according to the number of failed piezoelectric elements.

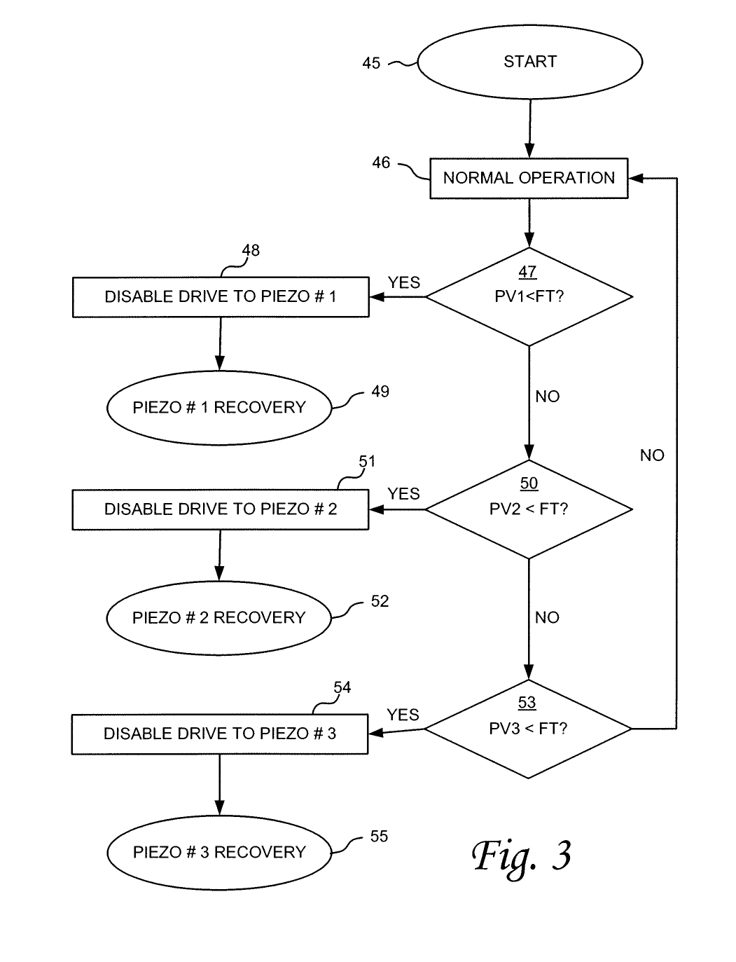

FIG. 3 is a flow chart illustrating a particular embodiment of a three-element piezoelectric actuator fault recovery system and method. At the start 45 of the flow, the system is operating normally 46. In a three-element embodiment, normal operation 46 entails: each of the three piezoelectric elements operating at substantially the normal voltage; the first drive signal routing to the first piezoelectric element; the second drive signal routing to the second piezoelectric element; and the third drive signal routing to the third piezoelectric element.

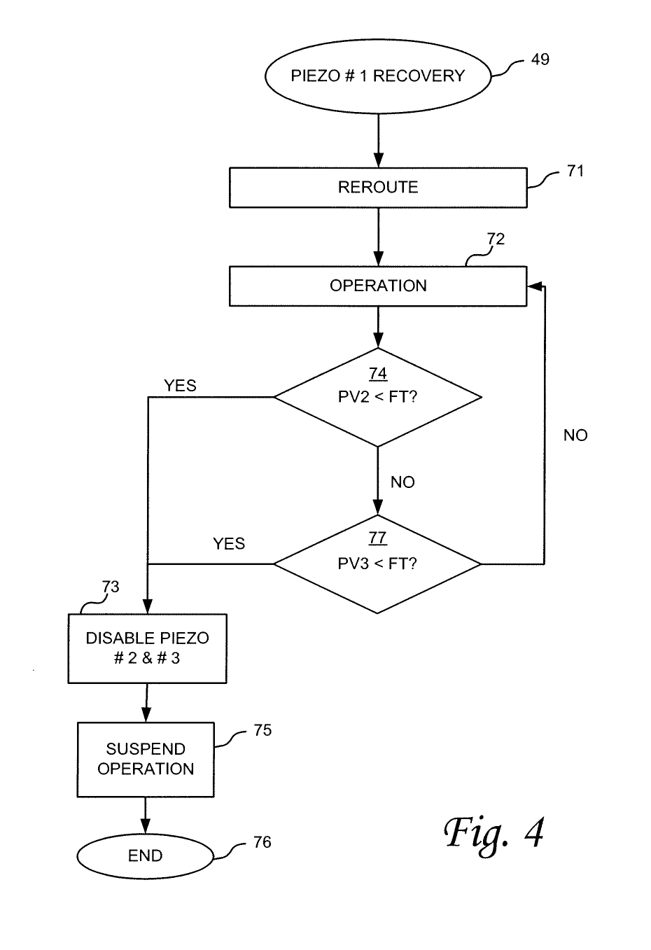

At inquiry 47, while the piezoelectric actuator is not actuating, the voltage across the first piezoelectric element is measured. If the voltage is less than a predetermined threshold voltage, then the element is considered to have failed. If failure occurs, the drive to the first piezoelectric element is disabled at step 48 and the system performs the first piezoelectric element recovery routine 49, as described with respect to FIG. 4. If failure does not occur, then the system proceeds to inquiry 50.

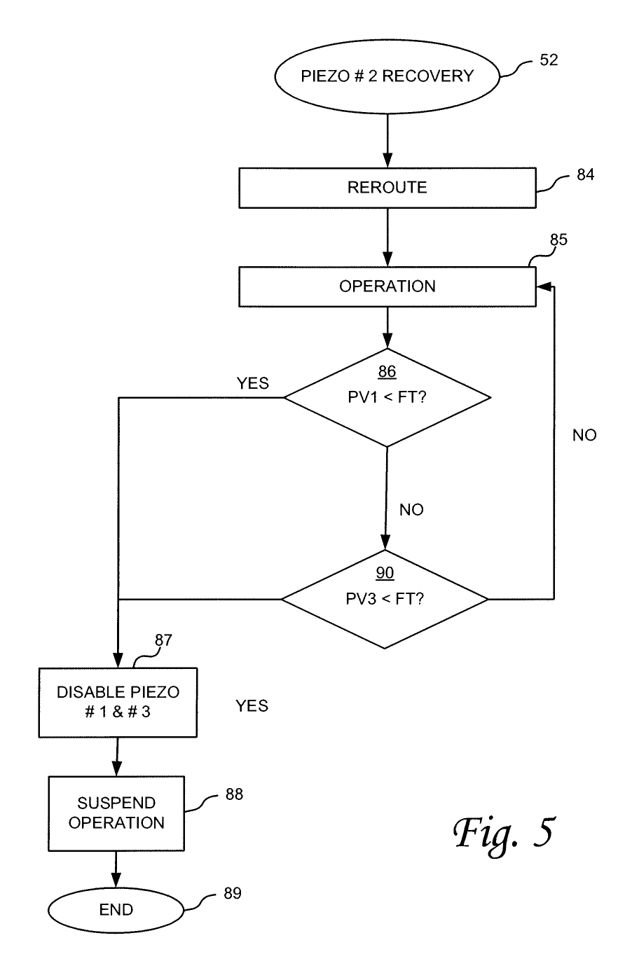

At inquiry 50, the voltage across the second piezoelectric element is measured. If the voltage is less than a predetermined threshold voltage, then the element is considered to have failed. If failure occurs, the drive to the second piezoelectric element is disabled at step 51 and the system performs the second piezoelectric element recovery routine 52, as described with respect to FIG. 5. If failure does not occur, then the system proceeds to inquiry 53.

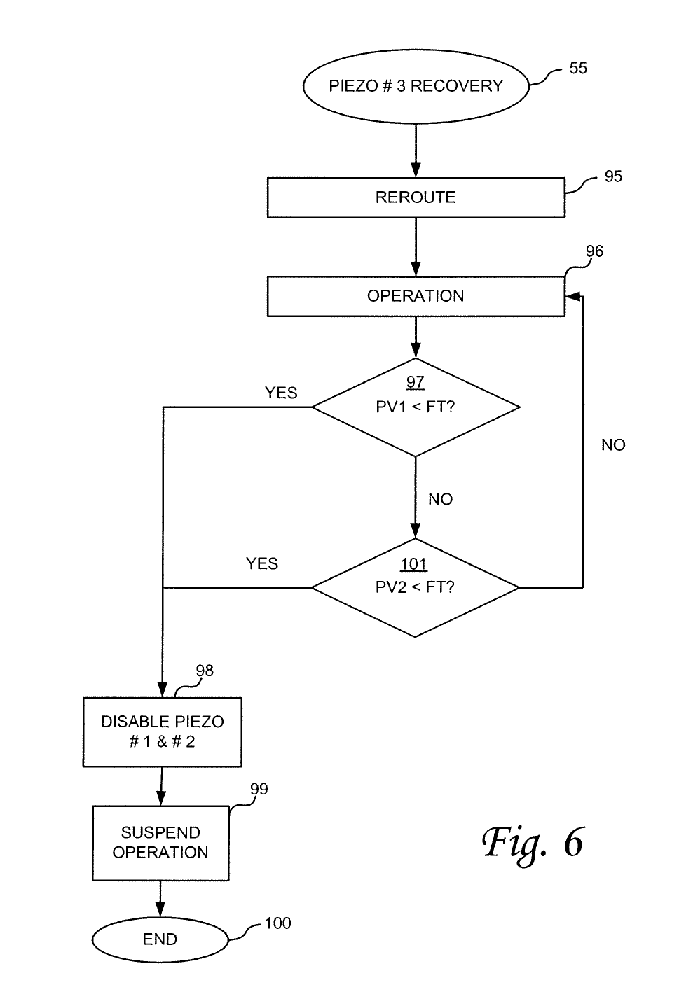

At inquiry 53, the voltage across the third piezoelectric element is measured. If the voltage is less than a predetermined threshold voltage, then the element is considered to have failed. If failure occurs, the drive to the third piezoelectric element is disabled at step 54 and the system performs the third piezoelectric element recovery routine 55, as described with respect to FIG. 6. If failure does not occur, then no piezoelectric element has failed and the system repeats the method starting at normal operation step 46.

FIG. 4 is a flow chart illustrating the first piezoelectric element recovery subroutine of a particular embodiment of a three-element piezoelectric actuator fault recovery system and method. At the start of the first element piezoelectric recovery subroutine, the drive signals are rerouted in step 71. The drive signals are rerouted so that the drive signal with the least impact on a desired actuator behavior is disabled, and the remaining drive signals are rerouted to the remaining piezoelectric elements. For example, if the desired actuator behavior were linearity of displacement with respect to time, and the third drive signal had the least impact on that behavior, then rerouting would comprise: (a) disabling the third drive signal; (b) routing the first drive signal to the second piezoelectric element; and (c) routing the second drive signal to the third piezoelectric element. As another example, in a fuel injector application, the actuator system may have a low power setting comprising two transmitted drive signals, and a high power setting comprising the two low power signals and a third high power drive signal. In this example, the desired actuator behavior is to continue operating the engine, so rerouting would comprise: (a) disabling the high power drive signal, and (b) rerouting the two lower power signals to the remaining two piezoelectric elements.

After the remaining drive signals have been rerouted to the remaining piezoelectric elements, operation 72 involves transmitting the drive signals to the piezoelectric elements. At inquiry 74, while the piezoelectric actuator is not operating, the voltage across the second piezoelectric element is measured. If the voltage is less than a predetermined threshold voltage, then the element is considered to have failed. In the particular illustrated embodiment, the system cannot continue to operate with only one operating piezoelectric element. For example, the system may be employed in a fuel injector, where two piezoelectric elements are required for the injector to operate at a low power setting. Accordingly, if failure occurs, the drives to the second and third piezoelectric elements are disabled at step 73. At step 75, the system suspends operation. In some embodiments, suspending operation may also include transmitting a signal, for example a message to a vehicle's electronic control unit indicating the system failure. Having suspended operations, the method ends at step 76. If failure does not occur, the system proceeds to inquiry 77. At inquiry 77, the voltage across the third piezoelectric element is measured. If the voltage is less than a predetermined threshold voltage, then the element is considered to have failed. If failure occurs, the method proceeds to step 73, as described herein. If inquiry 77 indicates that the third piezoelectric element is still functional, then the system repeats the method beginning with operation step 72.

FIG. 5 is a flow chart illustrating the second piezoelectric element recovery subroutine of a particular embodiment of a three-element piezoelectric actuator fault recovery system and method. At the start of the second element piezoelectric recovery subroutine, the drive signals are rerouted in step 84. The drive signals are rerouted so that the drive signal with the least impact on a desired actuator behavior is disabled, and the remaining drive signals are rerouted to the remaining piezoelectric elements. For example, if the desired actuator behavior were linearity of displacement with respect to time, and the third drive signal had the least impact on that behavior, then rerouting would comprise: (a) disabling the third drive signal; (b) continuing to route the first drive signal to the first piezoelectric element; and (c) routing the second drive signal to the third piezoelectric element. As another example, in a fuel injector application, the actuator system may have a low power setting comprising two transmitted drive signals, and a high power setting comprising the two low power signals and a third high power drive signal. In this example, the desired actuator behavior is to continue operating the engine, so rerouting would comprise: (a) disabling the high power drive signal, and (b) rerouting the two lower power signals to the remaining two piezoelectric elements.

After the remaining drive signals have been rerouted to the remaining piezoelectric elements, operation 85 involves transmitting the drive signals to the piezoelectric elements. At inquiry 86, while the piezoelectric actuator is not operating, the voltage across the first piezoelectric element is measured. If the voltage is less than a predetermined threshold voltage, then the element is considered to have failed. In the particular illustrated embodiment, the system cannot continue to operate with only one operating piezoelectric element. For example, the system may be employed in a fuel injector, where two piezoelectric elements are required for the injector to operate at a low power setting. Accordingly, if failure occurs, the drives to the first and third piezoelectric elements are disabled at step 87. At step 88, the system suspends operation. In some embodiments, suspending operation may also include transmitting a signal, for example a message to a vehicle's electronic control unit indicating the system failure. Having suspended operations, the method ends at step 89. If failure does not occur, the system proceeds to inquiry 90. At inquiry 90, the voltage across the third piezoelectric element is measured. If the voltage is less than a predetermined threshold voltage, then the element is considered to have failed. If failure occurs, the method proceeds to step 87, as described herein. If inquiry 90 indicates that the third piezoelectric element is still functional, then the system repeats the method beginning with operation step 85.

FIG. 6 is a flow chart illustrating the third piezoelectric element recovery subroutine of a particular embodiment of a three-element piezoelectric actuator fault recovery system and method. At the start of the third element piezoelectric recovery subroutine, the drive signals are rerouted in step 95. The drive signals are rerouted so that the drive signal with the least impact on a desired actuator behavior is disabled and the remaining drive signals are rerouted to the remaining piezoelectric elements. For example, if the desired actuator behavior were linearity of displacement with respect to time, and third drive signal had the least impact on that behavior, then rerouting would comprise: (a) disabling the third drive signal; (b) continuing to route the first drive signal to the first piezoelectric element; and (c) continuing to route the second drive signal to the second piezoelectric element. As another example, in a fuel injector application, the actuator system may have a low power setting comprising two transmitted drive signals, and a high power setting comprising the two low power signals and a third high power drive signal. In this example, the desired actuator behavior is to continue operating the engine, so rerouting would comprise: (a) disabling the high power drive signal, and (b) rerouting the two lower power signals to the remaining two piezoelectric elements.

After the remaining drive signals have been rerouted to the remaining piezoelectric elements, operation 96 involves transmitting the drive signals to the piezoelectric elements. At inquiry 97, while the piezoelectric actuator is not operating, the voltage across the third piezoelectric element is measured. If the voltage is less than a predetermined threshold voltage, then the element is considered to have failed. In the particular illustrated embodiment, the system cannot continue to operate with only one operating piezoelectric element. For example, the system may be employed in a fuel injector, where two piezoelectric elements are required for the injector to operate at a low power setting. Accordingly, if failure occurs, the drives to the first and second piezoelectric elements are disabled at step 98. At step 99, the system suspends operation. In some embodiments, suspending operation may also include transmitting a signal, for example a message to a vehicle's electronic control unit indicating the system failure. Having suspended operations, the method ends at step 100. If failure does not occur, the system proceeds to inquiry 101. At inquiry 101, the voltage across the third piezoelectric element is measured. If the voltage is less than a predetermined threshold voltage, then the element is considered to have failed. If failure occurs, the method proceeds to step 98, as described herein. If inquiry 101 indicates that the third piezoelectric element is still functional, then the system repeats the method beginning with operation step 96.

After reading this description it will be apparent to one of ordinary skill in the art how to extend the described example recovery system and method to piezoelectric actuators employing fewer or more piezoelectric elements. For example, in an actuator employing four elements, if one of the elements failed, there would be three remaining elements. The recovery subroutine for a four-element actuator would then be substantially similar to the fault recovery method of a three-element actuator according to FIGS. 3-6. As a further example, in an actuator employing three elements, the system may be able to continue operation using only one piezoelectric actuator element. The recovery subroutine would then comprise a further recovery subroutine in which one element was operated and monitored.

As used herein, the term module might describe a given unit of functionality that can be performed in accordance with one or more embodiments of the present invention. As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

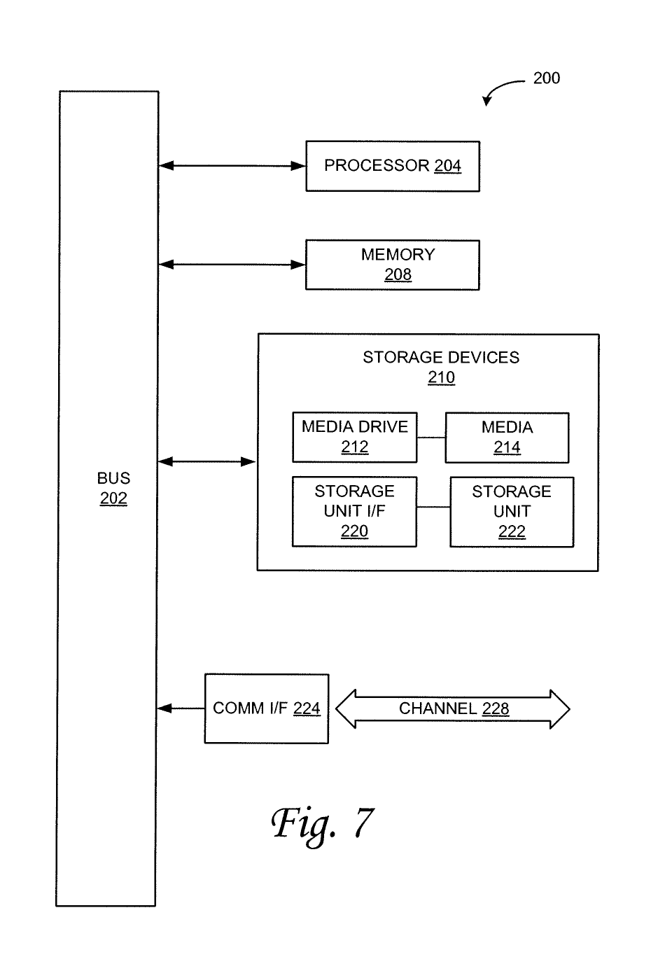

Various components and modules of the invention may be implemented using digital signal processing techniques. Where components or modules of the invention are implemented in whole or in part using software, in one embodiment, these software elements can be implemented to operate with a computing or processing module capable of carrying out the functionality described with respect thereto. One such example-computing module is shown in FIG. 7. Various embodiments are described in terms of this example-computing module 200. After reading this description, it will become apparent to a person skilled in the relevant art how to implement the invention using other computing modules or architectures.

Referring now to FIG. 7, computing module 200 may represent, for example, computing or processing capabilities found within desktop, laptop and notebook computers; hand-held computing devices (PDA's, smart phones, cell phones, palmtops, etc.); mainframes, supercomputers, workstations or servers; or any other type of special-purpose or general-purpose computing devices as may be desirable or appropriate for a given application or environment. Computing module 200 might also represent computing capabilities embedded within or otherwise available to a given device. For example, a computing module might be found in other electronic devices such as, for example, digital cameras, navigation systems, cellular telephones, portable computing devices, modems, routers, WAPs, terminals and other electronic devices that might include some form of processing capability.

Computing module 200 might include, for example, one or more processors, controllers, control modules, or other processing devices, such as a processor 204. Processor 204 might be implemented using a general-purpose or special-purpose processing engine such as, for example, a microprocessor, controller, or other control logic. In the example illustrated in FIG. 7, processor 204 is connected to a bus 202, although any communication medium can be used to facilitate interaction with other components of computing module 200 or to communicate externally.

Computing module 200 might also include one or more memory modules, simply referred to herein as main memory 208. For example, preferably random access memory (RAM) or other dynamic memory, might be used for storing information and instructions to be executed by processor 204. Main memory 208 might also be used for storing temporary variables or other intermediate information during execution of instructions to be executed by processor 204. Computing module 200 might likewise include a read only memory (“ROM”) or other static storage device coupled to bus 202 for storing static information and instructions for processor 204.

The computing module 200 might also include one or more various forms of information storage mechanism 210, which might include, for example, a media drive 212 and a storage unit interface 220. The media drive 212 might include a drive or other mechanism to support fixed or removable storage media 214. For example, a hard disk drive, a floppy disk drive, a magnetic tape drive, an optical disk drive, a CD or DVD drive (R or RW), or other removable or fixed media drive might be provided. Accordingly, storage media 214 might include, for example, a hard disk, a floppy disk, magnetic tape, cartridge, optical disk, a CD or DVD, or other fixed or removable medium that is read by, written to or accessed by media drive 212. As these examples illustrate, the storage media 214 can include a computer usable storage medium having stored therein computer software or data.

In alternative embodiments, information storage mechanism 210 might include other similar instrumentalities for allowing computer programs or other instructions or data to be loaded into computing module 200. Such instrumentalities might include, for example, a fixed or removable storage unit 222 and an interface 220. Examples of such storage elements 222 and interfaces 220 can include a program cartridge and cartridge interface, a removable memory (for example, a flash memory or other removable memory module) and memory slot, a PCMCIA slot and card, and other fixed or removable storage elements 222 and interfaces 220 that allow software and data to be transferred from the storage unit 222 to computing module 200.

Computing module 200 might also include a communications interface 224. Communications interface 224 might be used to allow software and data to be transferred between computing module 200 and external devices. Examples of communications interface 224 might include a modem or softmodem, a network interface (such as an Ethernet, network interface card, WiMedia, IEEE 802.XX or other interface), a communications port (such as for example, a USB port, IR port, RS232 port Bluetooth® interface, or other port), or other communications interface. Software and data transferred via communications interface 224 might typically be carried on signals, which can be electronic, electromagnetic (which includes optical) or other signals capable of being exchanged by a given communications interface 224. These signals might be provided to communications interface 224 via a channel 228. This channel 228 might carry signals and might be implemented using a wired or wireless communication medium. These signals can deliver the software and data from memory or other storage medium in one computing system to memory or other storage medium in computing system 200. Some examples of a channel might include a phone line, a cellular link, an RF link, an optical link, a network interface, a local or wide area network, and other wired or wireless communications channels.

In this document, the terms “computer program medium” and “computer usable medium” are used to generally refer to physical storage media such as, for example, memory 208, storage unit 220, and media 214. These and other various forms of computer program media or computer usable media may be involved in storing one or more sequences of one or more instructions to a processing device for execution. Such instructions embodied on the medium, are generally referred to as “computer program code” or a “computer program product” (which may be grouped in the form of computer programs or other groupings). When executed, such instructions might enable the computing module 200 to perform features or functions of the present invention as discussed herein.

While various embodiments of the present invention have been described above, it should be understood that they have been presented by way of example only, and not of limitation. Likewise, the various diagrams may depict an example architectural or other configuration for the invention, which is done to aid in understanding the features and functionality that can be included in the invention. The invention is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present invention. Also, a multitude of different constituent module names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the invention, whether or not such embodiments are described and whether or not such features are presented as being a part of a described embodiment. Thus, the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

1. A method of piezoelectric fault recovery, comprising:
monitoring a set of operational piezoelectric elements of a piezoelectric actuator;
detecting a failure of an element of the set; and
removing the failed element from the set.

2. The method of claim 1, wherein the step of detecting further comprises:
comparing a voltage across an element of the set with a threshold voltage; and
detecting a failure if the voltage is less than the threshold voltage.

3. The method of claim 2, wherein the step of comparing is performed when the element of the set is not actuating.

4. The method of claim 1, further comprising:
associating drive signals with the elements of the set of operational piezoelectric elements;
wherein the step of removing further comprises re-associating the drive signal formerly associated with the failed element with a different element of the set of operational piezoelectric elements.

5. The method of claim 1, wherein the step of removing further comprises disabling the actuator if less than a predetermined number of elements remain in the set of monitored elements.

6. The method of claim 5, wherein the predetermined number of elements corresponds to the number of elements required to operate a fuel injector at a predetermined power level.

7. A system for piezoelectric fault recovery, comprising:
a monitor for monitoring a set of operational piezoelectric elements of a piezoelectric actuator;
a detector coupled to the monitor for detecting a failure of an element of the set; and
a controller for removing the failed element from the set.

8. The system of claim 7, wherein the detector is configured to compare a voltage across an element of the set with a threshold voltage, and detect a failure if the voltage is less than the threshold voltage.

9. The system of claim 8, wherein the detector is configured to compare the voltage across an element of the set with a threshold voltage when the element of the set is not actuating.

10. The system of claim 7, wherein:
drive signals are associated with the elements of the set of operational piezoelectric elements; and
the controller re-associates the drive signal formerly associated with the failed element with a different element of the set of operational piezoelectric elements.

11. The system of claim 7, wherein the controller is further configured to disable the actuator if less than a predetermined number of elements remain in the set of monitored elements.

12. The system of claim 11, wherein the predetermined number of elements corresponds to the number of elements required to operate a fuel injector at a predetermined power level.

13. Computer executable program code embodied on a computer readable medium configured to cause a piezoelectric fault recovery system to perform the functions of:
monitoring a set of operational piezoelectric elements of a piezoelectric actuator;
detecting a failure of an element of the set; and
removing the failed element from the set.

14. The computer executable program code of claim 13, further configured to cause the piezoelectric fault recovery system to perform the functions of:
comparing a voltage across an element of the set with a threshold voltage; and
detecting a failure if the voltage is less than the threshold voltage.

15. The computer executable program code of claim 14, wherein the function of comparing is performed when the element of the set is not actuating.

16. The computer executable program code of claim 13, further configured to cause the piezoelectric fault recovery system to perform the functions of:
associating drive signals with the elements of the set of operational piezoelectric elements; and
re-associating the drive signal formerly associated with the failed element with a different element of the set of operational piezoelectric elements.

17. The computer executable program code of claim 13, further configured such that the function of removing further comprises disabling the actuator if less than a predetermined number of elements remain in the set of monitored elements.

18. The computer executable program code of claim 17, wherein the predetermined number of elements corresponds to the number of elements required to operate a fuel injector at a predetermined power level.
